(19) United States
(12) Patent Application Publication
(10) Pub. No.: US 2025/0301614 A1
(43) Pub. Date: Sep. 25, 2025

(54) Electromagnetic Shielding Box Assembly and Electromechanical Device

(71) Applicant: Robert Bosch GmbH, Stuttgart (DE)

(72) Inventor: Jinmei Liu, Suzhou (CN)

(21) Appl. No.: 19/081,689

(22) Filed: Mar. 17, 2025

(30) Foreign Application Priority Data
Mar. 22, 2024 (CN) 2024 2057 8091.6

(51) Int. Cl. H05K 9/00; B60R 16/023

(52) U.S. Cl. CPC H05K 9/0022; B60R 16/0239

(57) ABSTRACT

An electromagnetic shielding box assembly and an electromechanical device are disclosed. The electromagnetic shielding box assembly includes a housing, a shielding cover and a shielding lid. The shielding cover is arranged in the housing, and the shielding lid is arranged on the housing and the shielding cover to form a shielding space for arranging an electronic device therein. The housing has at least one through hole penetrating the housing, and the shielding cover has at least one first elastic portion. The first elastic portion extends outward from the body of the shielding cover, passes through the through hole, and then elastically abuts against a working component located outside the housing, thereby forming a conductive path from the shielding cover to the working component. By way of the above, lower costs, a simple connection process, and flexible, convenient installation and use are achieved, all while ensuring reliable performance.

This application claims priority under 35 U.S.C. § 119 to application no. CN 2024 2057 8091.6, filed on Mar. 22, 2024 in China, the disclosure of which is incorporated herein by reference in its entirety.

The present application relates to the field of electromagnetic shielding technology, and more specifically, to an electromagnetic shielding box assembly and an electromechanical device.

### BACKGROUND

When using electronic equipment, electromagnetic compatibility (EMC) becomes a concern. It is expected for the equipment to operate effectively within its electromagnetic environment, which involves two key aspects: first, it must resist external electromagnetic influences; second, it should not generate electromagnetic interference that could disrupt other devices. In particular, when electronic equipment operates in a harsh electromagnetic environment, having good electromagnetic compatibility is beneficial for ensuring the stability and safety of the system's performance.

Generally, suitable electromagnetic shielding methods can be employed to enable electronic equipment to achieve the electromagnetic compatibility required for specific applications. For example, electronic equipment can be placed within an appropriately designed electromagnetic shielding space to block or attenuate undesirable electromagnetic signals. Such electromagnetic shielding space typically consists of multiple layers of shielding housings made from metal materials such as copper, aluminum, and steel, which are assembled using screws, bolts, and other connectors. In some cases, these components are fixed together by welding, and these electromagnetic shielding devices usually utilize direct hard connections for grounding. After research, the present application found that most of the existing configuration methods, including those mentioned above, entail high costs, complex connection processes, and a lack of flexibility during installation and use, all of which negatively impact electromagnetic compatibility performance and can be improved.

### SUMMARY

In light of this, the present application provides an electromagnetic shielding box assembly and an electromechanical device designed to address, or at least mitigate, one or more of the aforementioned issues, as well as other challenges found in the prior art, or offer an alternative technical solution to existing methods.

According to one aspect of the present application, firstly, an electromagnetic shielding box assembly is provided, comprising a housing, a shielding cover and a shielding lid, wherein the shielding cover is arranged in the housing, and the shielding lid is arranged on the housing and the shielding cover to form a shielding space for arranging an electronic device therein, wherein the housing has at least one through hole penetrating the housing, and the shielding cover has at least one first elastic portion, wherein the first elastic portion extends outward from the body of the shielding cover, passes through the through hole, and then elastically abuts against a working component located outside the housing, thereby forming a conductive path from the shielding cover to the working component.

In the electromagnetic shielding box assembly according to the present application, optionally, the first elastic portion comprises a first part and a second part, wherein the first part is connected to the body of the shielding cover, and the second part is connected to the first part and has a curved section, wherein the curved section generates elastic deformation when abutting against the working component.

In the electromagnetic shielding box assembly according to the present application, optionally, the first part extends obliquely relative to the body of the shielding cover, and/or the first elastic portion also comprises a middle part, wherein the middle part is connected and arranged between the first part and the second part to form an arc transition.

In the electromagnetic shielding box assembly according to the present application, optionally, the first elastic portion is integrally formed with the body of the shielding cover, and/or at least a portion of the bottom outer surface of the shielding cover is adhesively bonded to the inner surface of the housing, and/or the shielding cover and the shielding lid are made of the same or different metal materials and the housing is made of insulating material.

In the electromagnetic shielding box assembly according to the present application, optionally, the housing has a joining portion, a first perforation and a first opening leading to the inner cavity of the housing, the shielding cover has a second elastic portion, a second perforation and a second opening leading to the inner cavity of the shielding cover, wherein the second opening is smaller than the first opening and is arranged in the same direction as the first opening, and the shielding lid has a protruding portion and an assembly portion matched with the joining portion, wherein, after the assembly portion and the joining portion are engaged, the shielding lid closes the first opening, and the protruding portion presses against the second elastic portion to generate elastic deformation, so that the shielding lid and the shielding cover abut against each other to close the second opening, and when the electronic device is arranged in the shielding space, it is electrically connected to the outside via the second perforation and the first perforation.

In the electromagnetic shielding box assembly according to the present application, optionally, the protruding portion and/or the assembly portion are configured as a bending structure, wherein the bending structure end of the protruding portion presses against the second elastic portion, and/or the assembly portion is configured as a groove shape and is arranged adjacent to the protruding portion, and/or the protruding portion is integrally formed with the body of the shielding lid, and/or the joining portion is arranged at the end of the side of the housing, and/or the joining portion and the assembly portion are adhesively bonded.

In the electromagnetic shielding box assembly according to the present application, optionally, the first perforation and the second perforation are respectively arranged at the bottom of the housing and the shielding cover, and the electronic device comprises a circuit board provided with a plug port, and the plug port is electrically connected to the outside via the second perforation and the first perforation.

Secondly, according to another aspect of the present application, an electromechanical device is also provided, comprising:
the electromagnetic shielding box assembly as described in any one of the above items;
an electronic device arranged in a shielding space of the electromagnetic shielding box assembly, the electronic device being insulated and spaced apart from the shielding cover and the shielding lid; and
a working component located outside the housing and connected to the housing, the first elastic portion of the shielding cover being elastically abutted against the working component, forming a conductive path from the shielding cover to the working component.

In the electromechanical device according to the present application, optionally, the conductive path is used for ground connection, and the working component is also electrically connected to the electronic device via a first perforation provided on the housing and a second perforation provided on the shielding cover to receive an output signal from the electronic device to operate.

In the electromechanical device according to the present application, optionally, the working component comprises a motor, and the electronic device comprises an ECU.

The present application offers several advantages, including lower costs, a simple connection process, and flexible, convenient installation and use, all while ensuring reliable performance. The use of a shielding cover with an elastic portion provides a dependable conductive path for the electromagnetic shielding box assembly, enhancing its electromagnetic compatibility performance. Furthermore, by embedding a metal cover within the insulating housing and forming a reliable elastic connection structure with the metal cover located above, a Faraday cage can be formed to achieve reliable electromagnetic shielding. This application addresses a gap in the use of such structures in the field of electromagnetic shielding, effectively reducing the significant reverse force often encountered with existing shielding components. It also allows for greater space for arranging electronic equipment, creating an optimal electromagnetic shielding environment for electronic equipment that improves the stability and safety of system operation.

### BRIEF DESCRIPTION OF THE DRAWINGS

FIG. 1 is a schematic diagram of a partial sectional structure of a side view of an electromechanical device according to an example of the present application, in which an electromagnetic shielding box assembly according to an example of the present application is configured.

FIG. 2 is a schematic diagram of a partial three-dimensional structure of the housing in the example of the electromagnetic shielding box assembly shown in FIG. 1.

FIG. 3 is a schematic diagram of a partial three-dimensional structure of the shielding cover in the example of the electromagnetic shielding box assembly shown in FIG. 1.

FIG. 4 is a schematic diagram of a partial three-dimensional structure after the housing and the shielding cover in the electromagnetic shielding box assembly shown in FIG. 1 are assembled.

### DETAILED DESCRIPTION

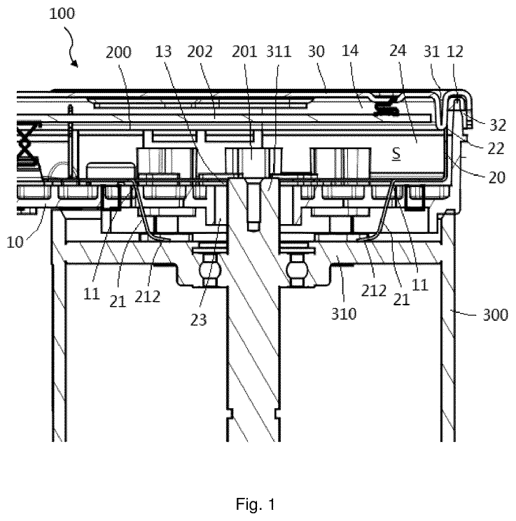

First of all, it should be noted that the descriptions of the electromagnetic shielding box assembly and the electromechanical device according to the present application are provided for illustrative purposes only and should not be interpreted as limiting the application. In this context, the technical terms “first” and “second” are used solely for differentiation and do not imply any specific order or relative significance. Additionally, the technical terms “upper”, “lower”, “right”, “left”, “bottom”, “top”, and their derivatives should be associated with the present application oriented as shown in FIG. 1. Unless explicitly stated otherwise, the present application may adopt various alternative orientations.

As an example, FIG. 1 schematically illustrates a general scenario of an example of the electromechanical device according to the present application, wherein an electromagnetic shielding box assembly 100, an electronic device 200, a working component 300 and an optional electrical connector (not shown) are provided, wherein the electronic device 200 is arranged in a shielding space S provided by the electromagnetic shielding box assembly 100. The working circuits, elements or components, units or modules on the electronic device 200 can be electrically connected to the working component 300, the electrical connector or other possible devices located outside the electromagnetic shielding box assembly 100 according to the needs of application, so as to realize the functional application required by the electromechanical device.

Specifically, the working component 300 may be a device for performing the intended function within the electromechanical device, such as a motor, a compressor, a pump, etc. The working component 300 can be optionally fixed to the outside of the housing 10 of the electromagnetic shielding box assembly 100 using connectors such as bolts and screws, and it can receive the output signals from the electronic device 200 via a connection port 311 to operate, for example, being controlled to perform various possible actions such as starting, standby, stopping, or running for a specified duration.

The electronic device 200 may be connected to the outside via one or more electrical connectors to transmit various possible electrical signals, electrical energy, etc. The specific configuration model, number of settings, layout position, etc. of the electrical connector can be designed accordingly according to the needs of application, and this application does not make any specific restrictions on this. For example, the electrical connector may be optionally fixed to the housing 10 of the electromagnetic shielding box assembly, such as forming a side-by-side arrangement with the working component 300 outside the housing.

It should be noted that the electromechanical device according to the present application may have a wide range of types, for example, it can include but not be limited to vehicle power steering, electronic compressor, hydraulic device, vehicle brake mechanism, etc. The electronic device 200 is installed in the electromagnetic shielding box assembly 100. It is used as a component of the electromechanical device to provide corresponding functional applications. For example, it can be used as an ECU (Electronic Control Unit) to control the operation of other parts in the electromechanical device (such as a steering gear), such as controlling the operation of the working component 300 (such as a motor). The electronic device 200 may have a circuit board 202, and any possible electronic elements or components, modules or units, such as resistors, capacitors, field effect transistors, integrated chips, plug ports, batteries, etc., may be configured for the electronic device 200 as needed. They are connected and arranged through the circuit layer on the circuit board 202 to form corresponding functional applications. In FIG. 1, the plug port 201 that may be optionally configured is schematically indicated using reference numeral 211. The circuit board 202 may use a printed circuit board (PCB) and may be designed to have a single-layer, two-layer or more-layer structure, which can be achieved by, for example, etching one or more copper layers.

The electromagnetic shielding box assembly 100 provides the shielding space S for the electronic device 200, which can effectively isolate or reduce the electromagnetic interference from the external environment to the electronic device 200, and can also shield the electronic device 200 from the external electromagnetic influence. When in use, in addition to possible grounding requirements, the electronic device 200 may be arranged to be insulated and separated from the components or parts of the electromagnetic shielding box assembly 100 that constitute the shielding space S, such as the shielding cover 20 and the shielding lid 30 described below, so as to ensure the effect of electromagnetic shielding.

In one or more embodiments, the electromagnetic shielding box assembly 100 may comprise a housing 10, a shielding cover 20 and a shielding lid 30, wherein the housing 10 may be made of one or more insulating materials such as plastic, ceramic, wood, etc., in a suitable configuration and size that meets application requirements, for example, plastic may be used to form the housing by injection molding.

As an example, the housing 10 may be provided with an opening 14. Through the opening 14 the inner cavity of the housing can be entered, and the shielding cover 20 and the electronic device 200 may be placed in the inner cavity of the housing 10 through the opening 14. A joining portion 12 may be arranged on the housing 10 and matched with the assembly portion 32 on the shielding lid 30, so as to join the shielding lid 30 and the housing 10 together. Optionally, the assembly portion 32 and the joining portion 12 may be glued and fixed using adhesive. For example, the assembly portion 32 may be configured into a suitable structure such as a groove. For example, a portion (such as the edge) of the shielding lid 30 may be bent or stamped to form a groove structure, and then the end of the side of the housing 10 may be bonded to the groove using adhesive; that is, the above-mentioned end of the housing 10 is directly used as the joining portion 12. This approach is straightforward and practical, helping to avoid complex structures and reduce costs. Of course, in other embodiments, the joining portion 12 and the assembly portion 32 matched therewith are allowed to have relatively complex structures. For example, a snap-on structure, a screw-on structure, etc. may be used.

One or more perforations 13 may be arranged on the housing 10 as required, and the perforation 13 is configured to penetrate the body of the housing 10, so as to provide a passage for the electronic device 200 to be electrically connected to the outside together with the perforation 23 located on the shielding cover 20. For example, elements or components (such as plug port) on the electronic device 200 or external elements or components (such as electrical connector) may be connected correspondingly via the perforation 13 and the perforation 23. As an example, the perforation 13 and the perforation 23 may be arranged at the bottom of the housing 10 and the shielding cover 20, respectively. When the circuit board 202 of the electronic device 200 is provided with a plug port 201, the plug port 201 may be optionally arranged to pass through the perforation 23 and the perforation 13, so as to electrically connect the electronic device 200 to a target object (such as a working component, a cable, an electrical connector, etc.) located outside the electromagnetic shielding box assembly 100. It should be understood that the arrangement position, the number of arrangements, the shape and size of the perforation 13 and the perforation 23 will be configured according to the application requirements. Moreover, sealing members such as rubber rings may be optionally arranged around the perforation 13 and/or perforation 23, so as to form close contact with components such as the plug port 201 passing through the above openings, thereby ensuring and improving the electromagnetic shielding effect of the electromagnetic shielding box assembly 100.

The shielding cover 20 is arranged in the housing 10 to construct the shielding space S. It can be made of one or more metal materials such as iron, steel, copper, aluminum, aluminum alloy, copper alloy, etc. to form a suitable configuration and size as needed to meet the application requirements of the electronic device 200. For example, it can be made of steel by stamping process and the thickness range is 1-5 mm. The shielding cover 20 has an opening 24 leading to the inside of the shielding cover. The electronic device 200 may be arranged in the inner cavity of the shielding cover 20 through the opening 24, and the inner cavity will constitute a part of the shielding space S. The opening 24 of the shielding cover 20 is smaller than the opening 14 of the housing 10. When the electromagnetic shielding box assembly 100 is assembled, the opening 24 and the opening 14 may be arranged in the same direction, and the two openings are closed by the shielding lid 30.

As an optional scenario, at least a portion of the outer surface of the bottom of the shielding cover 20 may be glued and fixed to the inner surface of the housing 10, so as to further enhance the structural stability of the shielding box, thereby providing a safer and more reliable working space for the electronic device 200. It should be understood by those skilled in the art that the bottom of the shielding cover 20, the bottom of the housing 10, or the top of the shielding cover 30 are allowed to have either a planar or non-planar structure. For example, the bottom of the shielding cover 20 and/or the housing 10 may be configured in a stepped shape, so as to fully adapt to the different configurations of various possible elements or components arranged on the circuit board 202 of the electronic device 200.

The shielding lid 30 may be made of the same or different metal material as the shielding cover 20. When it is covered on the housing 10, after the assembly portion 32 and the joining portion 12 discussed above are joined, housing opening 14 may be closed by the shielding cover 30. As an optional scenario of configuration, the protruding portion 31 provided on the shielding lid 30 and the elastic portion 22 provided on the shielding cover 20 may be matched to form an elastic connection structure. This arrangement not only realizes the closing operation of the shielding lid 30 for the opening 24 of the shielding cover 20, that is, forms the shielding space S defined by the shielding lid 30 and the shielding cover 20, thereby realizing a Faraday Cage to provide an electromagnetic shielding function, but also significantly reduces the matching force between the shielding lid 30 and the shielding cover 20 compared with the prior art. Additionally, this design increases the accommodating space of the shielding space S, and simplifies assembly and operation, ultimately reducing manufacturing complexity and costs.

Specifically, the protruding portion 31 and the elastic portion 22 may be respectively constructed at appropriate positions of the shielding lid 30 and the shielding cover 20. For example, the protruding portion 31 may be optionally arranged at a position adjacent to the assembly portion 32 to expand the volume of the shielding space S and ensure the structural strength. The elastic portion 22 may be arranged at the edge of the shielding cover 20, such as the end position of the side of the shielding cover 20. It can optionally have one or more bending sections, such as being roughly S-shaped, which may be achieved by, for example, casting or stamping processes, and the bending sections may provide elastic deformation ability of the elastic portion 22. The protruding portion 31 may optionally be constructed as a bending structure, such as being easily and cost-effectively obtained using a stamping process. The specific configuration of the bending structure may be flexibly configured as needed, such as being constructed into a U-shape, a V-shape, an L-shape, a triangle or any other suitable shape. When the shielding cover 20 is arranged inside the housing 10 and the shielding lid 30 is installed in place relative to the housing 10, the protruding portion 31 presses against the elastic portion 22, for example, by pressing against the elastic portion 22 through the end or side of the bending structure of the protruding portion 31, so that the elastic portion 22 generates elastic deformation after being pressed, and the shielding lid 30 and the shielding cover 20 abut against each other to close the opening 24 of the shielding cover 20, thereby providing a shielding space S for electromagnetic shielding.

By way of the elastic pressing force formed and maintained between the protruding portion 31 and the elastic portion 22, the shielding lid 30 and the shielding cover 20 can always maintain close contact through such an elastic connection structure, thereby ensuring that the shielding space S has good sealing properties. The electromagnetic shielding box assembly 100 can provide good electromagnetic compatibility for the electronic device arranged therein, and at the same time can effectively overcome the disadvantages of the hard connection methods commonly used in the prior art (such as bolts, screws or welding, etc.), such as large reverse force, the need for additional installation space, complex manufacturing and high cost.

According to the scheme of the present application, one or more through holes 11 penetrating the body of the housing may be provided on the housing 10 of the electromagnetic shielding box assembly as required, and one or more elastic portions 21 extending outward from the body of the shielding cover may be provided on the shielding cover 20. When the electromagnetic shielding box assembly is assembled, the elastic portion 21 may be extended through the corresponding through hole 11 so as to elastically abut against the working component 300 arranged outside the housing 10, thereby forming a conductive path from the shielding cover 20 to the working component 300. Such a conductive path may be used to achieve grounding processing, or even to transmit data signals, provide electrical energy, etc.

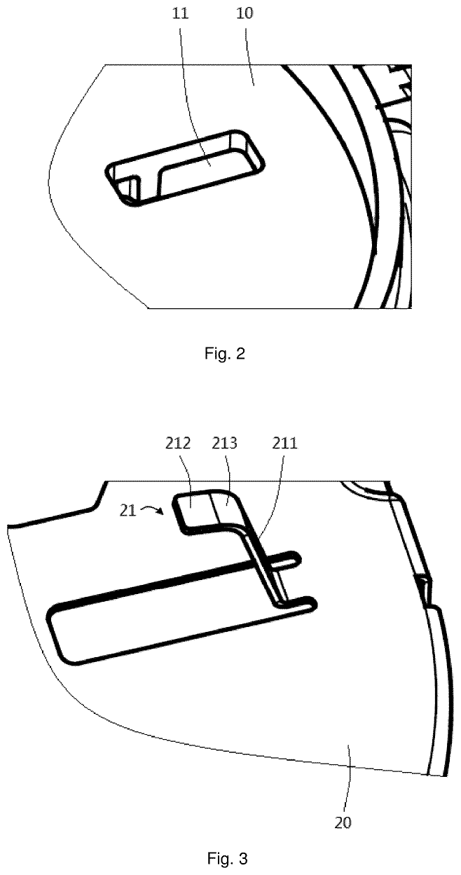

For example, a specific example of the elastic portion of the shielding cover and the through hole on the housing being used in cooperation is shown in a partially enlarged schematic manner in FIGS. 2 to 4. Specifically, the elastic portion 21 may be constructed to have three parts, namely, the first part 211, the second part 212 and the middle part 213. Among them, the middle part 213 is used to connect the first part 211 and the second part 212 and form an arc transition therebetween, which, on the one hand, enables the elastic portion to better achieve and maintain elastic deformation ability, and on the other hand, is also conducive to coordinating the overall force, avoiding problems such as stress concentration, so that the elastic portion can be used stably and reliably for a long time.

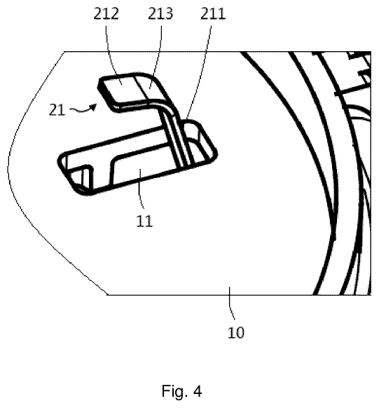

As shown in FIG. 1, FIG. 3 and FIG. 4, the elastic portion 21 may be integrally formed with the shielding cover 20 (e.g., by stamping, casting, etc.), so that the first part 211 extends outward from the body of the shielding cover. As an optional configuration option, the elastic portion 21 may form an inclined angle relative to the body of the shielding cover, and the specific angle range setting allows for configuration as needed to promote the elastic deformation ability of the elastic portion. In addition, the second part 212 of the elastic portion 21 may be configured to have a curved section, for example, by bending to form an arc profile or a more complex profile (such as an S-shape, etc.). Referring to the exemplary display in FIG. 1, when the second part 212 of the elastic portion 21 passes through the through hole 11 of the housing 10 and is pressed against the working component 300, for example, against a corresponding portion 310 on the working component 300 (such as the grounding portion, the connection port, etc. on the motor base), the above-mentioned curved section will produce elastic deformation after being pressed, so that the elastic portion 21 can be well kept in contact with the working component 300, thereby forming a stable and reliable conductive path for the electromagnetic shielding box assembly, for example, for grounding, or for transmitting signals or electrical energy, etc. According to the needs of application, those skilled in the art may configure the elastic portion 21 to have any suitable shape such as L-shape, S-shape or Z-shape for elastic connection.

It should be noted that, in one or some examples, the present application allows the elastic portion 21 to be made separately, and then fixed to the body of the shielding cover 20 by any feasible method such as welding, screw connection, etc., so as to construct a shielding cover with an elastic portion. Moreover, in one or some examples, the present application allows the structure to be simplified and the middle part 213 in the elastic portion 21 is omitted; that is, only the first part 211 and the second part 212 are provided. In addition, in one or some examples, the present application allows the shielding cover 20 to further form the conductive path with the electronic device 200 through any feasible conductive component such as a spring, a conductive pin, etc. Since the shielding cover 20 itself adopts conductive materials such as copper, aluminum, etc., a complete conductive path from the electronic device 200 to the working component 300 may be formed by way of the above conductive path and the conductive path provided by the elastic portion 21. When the electromagnetic shielding box assembly is utilized, such a complete conductive path may be conveniently and reliably used for purposes such as grounding, signal transmission, or electrical energy transfer, as required.

The electromagnetic shielding box assembly and the electromechanical device according to the present application are described in detail by way of example only. These examples only serve to demonstrate the principles and implementation methods of the present application, and do not constitute a limitation on the present application. Without departing from the scope of the present application, those skilled in the art may also make various modifications and improvements. Therefore, all equivalent technical solutions shall fall within the scope of the present application and be defined by the various claims of the present application.

What is claimed is:

1. An electromagnetic shielding box assembly, comprising:
a housing;
a shielding cover, and
a shielding lid,
wherein the shielding cover is arranged in the housing,
wherein the shielding lid is arranged on the housing and the shielding cover to form a shielding space configured to receive an electronic device therein,
wherein the housing has at least one through hole configured to penetrate the housing,
wherein the shielding cover has at least one first elastic portion, and
wherein the first elastic portion is configured to extend outward from the body of the shielding cover, pass through the through hole and then elastically abut against a working component located outside of the housing so as to form a conductive path from the shielding cover to the working component.

2. The electromagnetic shielding box assembly according to claim 1, wherein:
the first elastic portion comprises a first part and a second part,
the first part is connected to the body of the shielding cover, and the second part is connected to the first part and has a curved section, and
the curved section is configured to generate elastic deformation when abutting against the working component.

3. The electromagnetic shielding box assembly according to claim 2, wherein:
the first part extends obliquely relative to the body of the shielding cover, and/or the first elastic portion also comprises a middle part, and
the middle part is connected and arranged between the first part and the second part to form an arc transition.

4. The electromagnetic shielding box assembly according to claim 1, wherein the first elastic portion is integrally formed with the body of the shielding cover, and/or at least a portion of the bottom outer surface of the shielding cover is adhesively bonded to the inner surface of the housing, and/or the shielding cover and the shielding lid are made of the same or different metal materials and the housing is made of insulating material.

5. The electromagnetic shielding box assembly according to claim 1, wherein the housing has a joining portion, a first perforation and a first opening leading to the inner cavity of the housing, the shielding cover has a second elastic portion, a second perforation and a second opening leading to the inner cavity of the shielding cover, wherein the second opening is smaller than the first opening and is arranged in the same direction as the first opening, and the shielding lid has a protruding portion and an assembly portion matched with the joining portion, wherein, after the assembly portion and the joining portion are engaged, the shielding lid closes the first opening, and the protruding portion presses against the second elastic portion to generate elastic deformation, so that the shielding lid and the shielding cover abut against each other to close the second opening, and when the electronic device is arranged in the shielding space, it is electrically connected to the outside via the second perforation and the first perforation.

6. The electromagnetic shielding box assembly according to claim 5, wherein the protruding portion and/or the assembly portion are configured as a bending structure, wherein the bending structure end of the protruding portion presses against the second elastic portion, and/or the assembly portion is configured as a groove shape and is arranged adjacent to the protruding portion, and/or the protruding portion is integrally formed with the body of the shielding lid, and/or the joining portion is arranged at the end of the side of the housing, and/or the joining portion and the assembly portion are adhesively bonded.

7. The electromagnetic shielding box assembly according to claim 5, wherein the first perforation and the second perforation are respectively arranged at the bottom of the housing and the shielding cover, and the electronic device comprises a circuit board provided with a plug port, and the plug port is electrically connected to the outside via the second perforation and the first perforation.

8. An electromechanical device, comprising:
the electromagnetic shielding box assembly as claimed in claim 1;
an electronic device arranged in the shielding space of the electromagnetic shielding box assembly, the electronic device being insulated and spaced apart from the shielding cover and the shielding lid; and
a working component located outside of the housing and connected to the housing, the first elastic portion of the shielding cover being elastically abutted against the working component so as to form a conductive path from the shielding cover to the working component.

9. The electromechanical device according to claim 8, wherein the conductive path is configured to be used for ground connection, and the working component is also electrically connected to the electronic device via a first perforation provided on the housing and a second perforation provided on the shielding cover to receive an output signal from the electronic device to operate.

10. The electromechanical device according to claim 8, wherein:
the working component comprises a motor, and
the electronic device comprises an ECU.
